(19) United States
(12) Patent Application Publication
(10) Pub. No.: US 2007/0212655 A1
(43) Pub. Date: Sep. 13, 2007

(54) Method for applying T-shaped photo-resist pattern to fabricate a wiring pattern with small structural dimensions

(76) Inventors: Kuo-Kuei Fu, Shanghai (CN); Meng-Hsing Chou, Shanghai (CN)

Correspondence Address: ROSENBERG, KLEIN & LEE, 3458 ELLICOTT CENTER DRIVE-SUITE 101, ELLICOTT CITY, MD, 21043, US

(21) Appl. No.: 11/373,143

(22) Filed: Mar. 13, 2006

(51) Int. Cl. G03F 7/26

(52) U.S. Cl. 430/325; 430/322

(57) ABSTRACT

A method for applying T-shaped photo-resist pattern to fabricate a wiring pattern with small structural dimensions. According to the hydroxyl of a chemical-magnified photo-resist layer must participate in a reaction to be able to fabricate the desired exposure pattern, the chemical photo-resist layer is used to form on the semiconductor substrate wafer. By providing an ammonium gas to semiconductor substrate wafers, it causes NH₃— to catch the H+ ion of the upper site of the chemical-amplified photo-resist layer. This causes a non-reactive layer over the upper portion when the patterning process for chemical-magnified photo-resist layer is performed, and then to fabricate the T-shaped photo-resist pattern. Furthermore, when the wiring pattern is deposited over the semiconductor substrate wafer, it could be able to form the wiring pattern with small structural dimensions.

### FIELD OF THE INVENTION

1. Field of the Invention

The present invention relates to a method for fabricating a wiring pattern, especially as it relates to a method of applying T-shaped photo-resist pattern to fabricate a wiring pattern with small structural dimensions.

2. Description of the Related Art

For many years, the development of integrated photo-resist technology always follows Moore's Law. Approximately every 18 months, the quantity of transistors doubles and continuously increases the density of ICs on semiconductor substrate wafers. This increases the speed and function of the IC. However, nowadays the achievable resolution of optical design for photolithography system has reached its limit. In order to enhance the resolution limit, special methods referred to as “optical-proximity correction” (OPC) and “phase-shift mask” (PSM) are used.

When photo mask structures have structural sizes smaller than the wavelengths of exposure of photo light source used, for example, in the tiny rectangular photo-resist pattern, light diffusion effect causes the rounding of edges from four corners of photo-resist pattern. Therefore, it needs to use the optical-proximity correction method to add in an auxiliary pattern or to alter the pattern lines. The phase-shift mask is a method which adds a phase-shift layer over a portion of the mask. Though, the method of using the optical-proximity correction or the phase-shift mask can fabricate the deep-submicron circuits. However, one disadvantage is that the complexity of fabricating, testing and designing for photo mask and, causes high production cost.

In view of the foregoing, therefore, the present invention proposes a method for applying T-shaped photo-resist pattern to fabricate a wiring pattern with small structural dimensions under the premise of saving new materials, to fabricate a wiring pattern with deep-submicron size, furthermore, highly reduces the manufacturing cost for efficiently increasing market competition strength.

### SUMMARY OF THE INVENTION

The the present invention provides a method for applying T-shaped photo-resist pattern to fabricate a wiring pattern with small structural dimensions, in order to effectively reduce the fabricating cost of the deep-submicron process, and then forms a wiring pattern with small structural dimensions.

Another aspect of the present invention is to provide a method for applying T-shaped photo-resist pattern to fabricate a wiring pattern with small structural dimensions, wherein there is no need to use a high cost phase-shift mask for fabricating a same wiring pattern using deep-submicron fabricating process.

The invention further relates a method for applying T-shaped photo-resist pattern to fabricate a wiring pattern with small structural dimensions, wherein it takes advantage of the characteristics of the present day chemical-amplified photo-resist material to fabricate a wiring pattern with small structural dimensions.

In order to reach the above goals, the present invention provides a method for applying T-shaped photo-resist pattern to fabricate a wiring pattern with small structural dimensions. This process comprises the steps of providing a semiconductor substrate wafer; then fabricating a chemical-magnified photo-resist layer on the semiconductor substrate wafer; and using a photo mask to carry out exposure operation over the chemical-amplified photo-resist layer, then providing an ammonia gas to the semiconductor substrate wafer, having NH3_ ion to catch the H+ ion of the upper portion of the chemical-magnified photo-resist layer. It then uses the bake-and-exposure operation to the chemical-magnified photo-resist layer for fabricating a T-shaped patterned photo-resist layer. Meanwhile, it uses the T-shaped patterned photo-resist layer as a mask to fabricate a wiring pattern deposited on the semiconductor substrate wafer, finally, removing the T-shaped patterned photo-resist layer to fabricate a wiring pattern with small structural dimensions.

Hereinafter, embodiments of the invention are discussed below with reference to the Figures.

### BRIEF DESCRIPTION OF THE DRAWINGS

FIGS. 1-5 are sectional views of present invention.

### DETAILED DESCRIPTION OF THE PREFERRED EMBODIMENTS

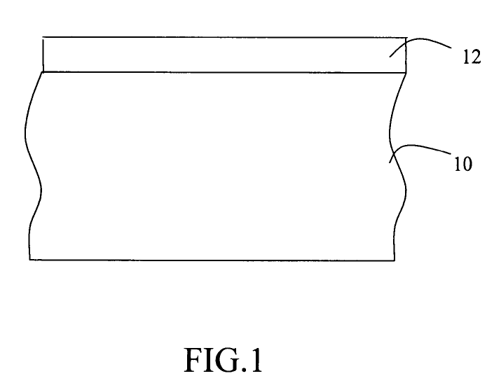

The present invention relates to a method for applying T-shaped photo-resist pattern to fabricate a wiring pattern with small structural dimensions, FIGS. 1 to 5 show cross-sectional views of fabrication stages relating to an preferred implementation of the method.

FIG. 1. illustrates an example of a chemical-amplified photo-resist layer 12 fabricating over the semiconductor substrate wafer 10. A matrix resin of the chemical-amplified photo-resist 12 is selected from the cresol-novolac or the poly-hydroxyl-styrene, and the poly-acid generator of the chemical-amplified photo-resist 12 is selected form the onium-salt or the S-triazine derivative. A crosslinking agent of the chemical-amplified photo-resist 12 is selected from melamine derivative or benzyl alcohol derivative.

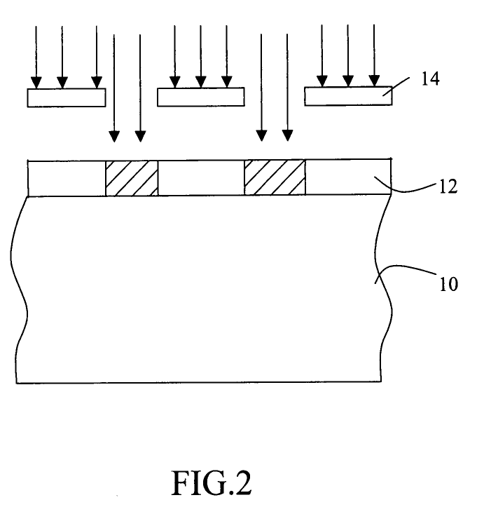

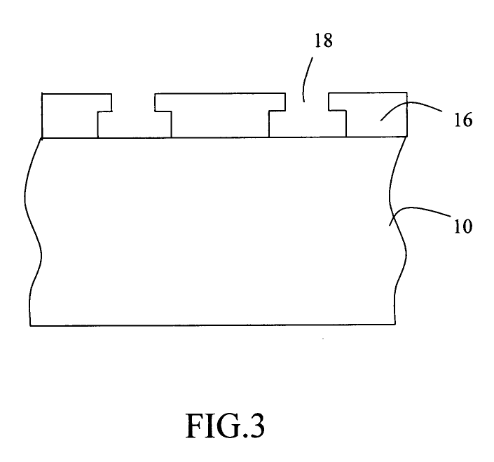

FIG. 2 illustrates an example of exposure activity of a chemical amplified photo-resist layer 12 where a wide wiring pattern is used as a photo mask. The chemical-amplified photo-resist layer 12 is masked by the OH— protection site of the polyhydroxy styrene, by coordinating with the photo-acid generator, then turn into the un-dissolved resin with alkali image solution. Therefore when the exposure activities to chemical-amplified photo-resist layer 12 are underway, the protection site will be decomposing by photo-acid generator of the chemical-amplified photo-resist layer 12 (As shown in FIG. 2, the oblique lines denote a resin with photo decomposing reaction), therefore exposing the OH— protection site (not shown in diagram). After providing an ammonium gas over semiconductor substrate wafers 10, having NH₃— to catch the H+ ion of the upper portion of the chemical-amplified photo-resist layer, the H+ ion in a deficient state causes the upper portion of the chemical-amplified photo-resist layer unable to be developed. Further, applied a baking process at 100° C. to the chemical-amplified photo-resist layer 12 in order to accelerate bond breaking of photo-resist, then to form a potential image by chemical-amplified photo-resist layer 12. Finally, it carries out the development procedure to fabricate a T-shaped patterned photo-resist layer 16 as shown in FIG. 3.

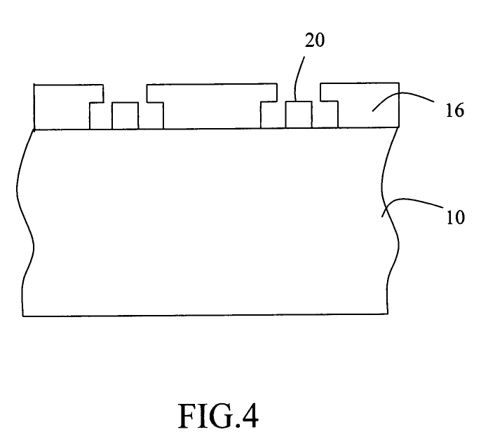

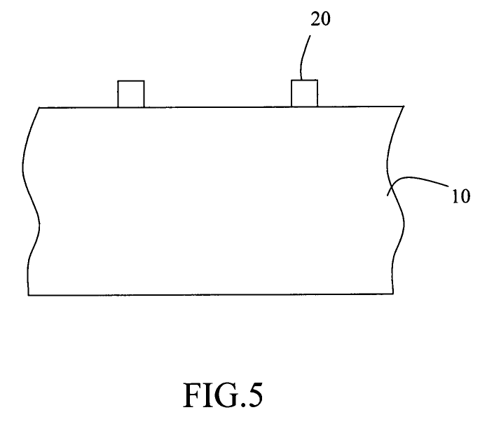

Further, use the T-shaped patterned photo-resist layer 16 as a mask to deposit a wiring layer over the semiconductor substrate wafer 10. The wiring layer could be a metallic-silicon or a poly-silicon layer. Now the T-shaped patterned photo-resist layer 16 which has a wide T-shaped size over the top portion causes the ion beam which comes through etching window 18 to shrink, fabricating a small wiring pattern 20 over the semiconductor substrate wafers 10, as shown in FIG. 4, and then removes the T-shaped patterned photo-resist layer 16, to fabricate a wiring pattern with small dimensional structure 20, as shown in FIG. 5.

The present invention relates to a method for applying T-shaped photo-resist to fabricate a wiring pattern with small structural dimensions, wherein using the current characteristics of chemical-amplified photo-resist to fabricate a small dimensional wiring pattern with high density ICs. This reduces the cost, furthermore gives it competitive strength.

The above described embodiments are for explaining technical concepts and features. Those skilled in the art will appreciate that with various modifications, substitution is possible, without departing from the scope of the inventions as disclosed in the accompanying claims.

What is claimed is:

1. A method for applying T-shaped photo-resist pattern to fabricate a wiring pattern with small structural dimensions, which comprises the steps of:
providing a semiconductor substrate wafer;
fabricating a chemical-magnified photo-resist layer on the semiconductor substrate wafer;
using a photo mask to carry out exposure operation over the chemical-amplified photo-resist layer;
providing ammonia gas to the semiconductor substrate wafer, having NH₃— ion to catch H+ ion of upper portion of the chemical-magnified photo-resist layer;
performing bake-and-exposure operation to the chemical-magnified photo-resist layer for fabricating a T-shaped patterned photo-resist layer; using the T-shaped patterned photo-resist layer as a mask to fabricate a wiring pattern deposited on the semiconductor substrate wafer; and
removing the T-shaped patterned photo-resist layer.

2. The method of claim 1, wherein a matrix resin ingredient of the chemical-amplified photo-resist layer is selected from eresol novalac or poly hydroxyl styrene.

3. The method of claim 1, wherein a poly-acid generator of the chemical-amplified photo-resist layer is selected from onium salt or S-triazine derivative.

4. The method of claim 1, wherein a crosslinking agent for the chemical-amplified photo-resist layer is selected from melamine derivative or benzyl alcohol derivative.

5. The method of claim 1, wherein a temperature for baking the chemical-amplified photo-resist layer is set to 100° C.

6. The method of claim 1, wherein the material of the wiring pattern is selected from metallic-silicon or poly-silicon.
